(19) United States
(12) Patent Application Publication
(10) Pub. No.: US 2026/0150525 A1
(43) Pub. Date: May 28, 2026

(54) DISPLAY DEVICE, METHOD OF PROVIDING THE SAME AND ELECTRONIC DEVICE INCLUDING THE SAME

(71) Applicant: Samsung Display Co., LTD., Yongin-si (KR)

(72) Inventor: Hyun Eok SHIN, Yongin-si (KR)

(21) Appl. No.: 19/336,758

(22) Filed: Sep. 23, 2025

(30) Foreign Application Priority Data
Nov. 22, 2024 (KR) 10-2024-0168486

(51) Int. Cl. H10K 59/123; H10K 59/12; H10K 59/124; H10K 71/60

(52) U.S. Cl. CPC H10K 59/123; H10K 59/1201; H10K 59/124; H10K 71/60

(57) ABSTRACT

A display device includes a transistor connected to the light-emitting element and including an active layer including a contact region and a channel region and a gate electrode overlapping the channel region, an insulating layer between the active layer and the light-emitting element and including a contact hole therein through which the contact region is exposed, and a contact electrode electrically connecting the light-emitting element to the transistor and including a lower contact including a contact portion connected to the active layer, and an overhang portion which extends from the contact portion, in a direction away from the contact hole, and an upper contact which is in the contact hole, and directly contacts the lower contact at the overhang portion.

This application claims priority to Korean Patent Application No. 10-2024-0168486 filed on Nov. 22, 2024, and all the benefits accruing therefrom under 35 U.S.C. § 119, the entire disclosure of which is incorporated by reference herein.

### BACKGROUND

### (1) Field

Embodiments of the present disclosure relate to a display device, a method of manufacturing (or providing) the same, and electronic device including the same. More particularly, embodiments of the present disclosure relate to a display device including a transistor and electrode, a method of manufacturing (or providing) the display device, and electronic device including the display device.

### (2) Description of the Related Art

In a display device such as an organic light-emitting diode (OLED) display device and a liquid crystal display (LCD) device, a display substrate including, e.g., a thin film transistor (TFT) and various wirings may be provided, and a display structure including electrodes and emission layers may be formed (or providing) on the display substrate.

For example, electrodes connecting the TFT and the display structure may be disposed. Various constructions of the TFT and the electrodes for stable implementation of a high-resolution display device have been researched

### SUMMARY

According to an embodiment of the present disclosure, there is provided a display device having improved electrical properties and structural reliability.

According to an embodiment of the present disclosure, there is provided a method of manufacturing a display device having improved electrical properties and structural reliability.

According to an embodiment of the present disclosure, there is provided an electronic device having improved electrical properties and structural reliability.

A display device may include a light-emitting element; a transistor connected to the light-emitting element, the transistor including an active layer including a contact region and a channel region, and a gate electrode overlapping the channel region of the active layer; an insulating layer which is between the active layer and the light-emitting element, the insulating layer including a contact hole therein through which the contact region of the active layer is exposed; and a contact electrode electrically connecting the light-emitting element to the transistor, at the contact region of the active layer, the contact electrode including a lower contact and an upper contact. The lower contact may include a first contact portion connected to the contact region of the active layer in the contact hole, and a first overhang portion which extends from the first contact portion, in a direction away from the contact hole, and has a curved surface. The upper contact may be in the contact hole, and may directly contact the lower contact at the curved surface of the first overhang portion.

In some embodiments, the first contact portion may define a first recess of the lower contact which is open at a first inlet of the lower contact, the first inlet being defined by the first overhang portion and having a width. The contact hole may have a first width corresponding the first contact portion of the lower contact, and the width of the first inlet may be smaller than the first width of the contact hole.

In some embodiments, the width of the first inlet may be about 50% or less of the first width of the contact hole.

In some embodiments, the first inlet and the first recess of the lower contact may be closed by the upper contact.

In some embodiments, the display device may further include an insulating filler in the first recess which is closed by the upper contact.

In some embodiments, the insulating filler may have a void defined therein.

In some embodiments, the void may be surrounded by the insulating filler.

In some embodiments, the insulating layer may include a first insulating interlayer covering the active layer and the gate electrode, the first insulating interlayer including a first contact hole defined therein which exposes the contact region of the active layer and has the first width; and a second insulating interlayer on the first insulating interlayer, the second insulating interlayer including a second contact hole defined therein which exposes the first overhang portion of the lower contact. The upper contact may include a second contact portion which contacts the first overhang portion, and covers the first inlet of the lower contact in the second contact hole, and a second overhang portion which extends from the second contact portion, in a direction away from the second contact hole.

In some embodiments, a bottom portion of the second contact portion may include a tip portion which protrudes toward a bottom surface of the lower contact.

In some embodiments, the second contact portion may define a second recess of the upper contact which is open at a second inlet of the upper contact, the second inlet being defined by the second overhang portion and having a width. The contact hole may a second width corresponding to the second contact portion of the upper contact. The width of the second inlet may be smaller than the second width of the second contact hole, and greater than or equal to the width of the first inlet of the lower contact.

In some embodiments, the display device may include a planarization layer which is on the second insulating interlayer and extends into the second recess of the upper contact to fill the second recess.

In some embodiments, the planarization layer which is in the second recess includes a void defined therein.

In some embodiments, the lower contact may include a first metal layer, a second metal layer and a third metal layer sequentially stacked from an inner wall of the contact hole and from a top surface of the contact region of the active layer.

In some embodiments, the first metal layer and the third metal layer may include a same metal. The second metal layer may include a metal different from that of the first metal layer and the third metal layer, and may have a thickness greater than a thickness of each of the first metal layer and the third metal layer.

In some embodiments, the first metal layer and the third metal layer may include titanium, and the second metal layer may include aluminum.

A method of providing a display device may include providing a transistor comprising an active layer and a gate electrode which overlaps the active layer, on a base substrate; and providing a contact electrode which electrically connects the transistor to a light-emitting element. The providing of the contact electrode may include providing a first insulating interlayer covering the gate electrode of the transistor; etching the first insulating interlayer to provide a first contact hole which is in the first insulating interlayer and exposes the active layer; providing a lower contact of the contact electrode, the lower contact including a first contact portion which is in the first contact hole, defines a first recess of the lower contact, and is connected to the active layer, and a first overhang portion which extends from the first contact portion and to an outside of the first contact hole; providing a second insulating interlayer on the first insulating interlayer, extending into the first recess of the lower contact, and covering the lower contact; etching the second insulating interlayer to provide a second contact hole which is in the second insulating interlayer, and exposes the first overhang portion of the lower contact, the etching of the second insulating interlayer separating a portion of the second insulating interlayer which is in the first recess from a remainder of the second insulating interlayer; and providing an upper contact of the contact electrode which is in the second contact hole and contacts the lower contact at the first overhang portion of the lower contact.

In some embodiments, the providing of the second insulating interlayer may form a void in the portion of the second insulating interlayer which is in the first recess.

In some embodiments, the portion of the second insulating interlayer may fill the first recess.

An electronic device may include a display device; a memory; and a processor executing data included in the memory and controlling an operation of the display device. The display device may include a light-emitting element; a transistor connected to the light-emitting element, the transistor including an active layer including a contact region and a channel region, and a gate electrode overlapping the channel region of the active layer; an insulating layer which is between the active layer and the light-emitting element, the insulating layer including a contact hole therein through which the contact region of the active layer is exposed; and a contact electrode electrically connecting the light-emitting element to the transistor, at the contact region of the active layer, the contact electrode including a lower contact and an upper contact. The lower contact may include a first contact portion connected to the contact region of the active layer in the contact hole, and a first overhang portion which extends from the first contact portion, in a direction away from the contact hole, and has a curved surface. The upper contact may be in the contact hole, and may directly contact the lower contact at the curved surface of the first overhang portion.

In some embodiments, the electronic device may include a virtual reality glass, an augmented reality glass, a smart phone, a tablet PC, a laptop, a television, a desk monitor, smart glasses, a head-mounted display, a smart watch or a vehicle display.

In a display device according to embodiments of the invention, a transistor and a light-emitting element may be electrically connected to each other via a contact electrode having a multi-layered structure stacked by an overhang. Accordingly, a contact electrode structure having a high aspect ratio included in a high-resolution display device may be stably implemented. Additionally, disconnection in the contact electrode and excessive expansion of a void in a contact hole due to a step coverage limitation in a contact electrode fabrication may also be suppressed.

### BRIEF DESCRIPTION OF THE DRAWINGS

FIG. 1 is a schematic cross-sectional view of a display unit in a display panel or a display device including a thin film transistor according to embodiments.

FIG. 2 is a partially enlarged cross-sectional view of a lower contact and structures which are adjacent to the lower contact of FIG. 1.

FIG. 3 is a schematic cross-sectional view of a display unit in a display panel or a display device including a thin film transistor according to embodiments.

FIG. 4 is a partially enlarged cross-sectional view of a stacked structure of a lower contact and an upper contact of FIG. 3.

FIGS. 5 and 6 are schematic cross-sectional views illustrating light-emitting elements according to embodiments.

FIGS. 7 to 13 are schematic cross-sectional views describing a method of manufacturing a display panel or a display device according to embodiments.

FIG. 14 is an exploded perspective view illustrating an electronic device according to embodiments.

FIG. 15 is a schematic plan view illustrating an arrangement of pixels of a display device included in an electronic device according to embodiments.

FIG. 16 is a pixel equivalent circuit diagram of a display device according to embodiments.

FIG. 17 is a block diagram of an electronic device in accordance with an embodiment.

FIG. 18 is a schematic diagram of an electronic device in accordance with various embodiments.

### DETAILED DESCRIPTION

Hereinafter, embodiments of the invention will be described in more detail with reference to the attached drawings. The same reference numerals can be used for indicating the same elements in the drawings, and repeated descriptions of the same elements can be omitted. Within the Figures and the text of the disclosure, a reference number indicating a singular form of an element may also be used to reference a plurality of the element.

Embodiments disclosed in the attached drawings are exemplary, and are to be understood to include all modifications, equivalents and substitutes included in the spirit and technical scope of the invention.

The terms “on”, “connected”, “coupled,” etc., used herein refers to a direct placement/connection/combination, and also refers to a case where another element is interposed two different elements. For example, when an element is referred to as being related to another element such as being “on” another element, it can be directly on the other element or intervening elements may be present therebetween. In contrast, when an element is referred to as being related to another element such as being “directly on” another element, there are no intervening elements present.

The terms such as “first”, “second”, “below”, “below”, “above,” “above,” etc., are used in a relative sense to distinguish different elements or positions, and do not specify an absolute position or an absolute order.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

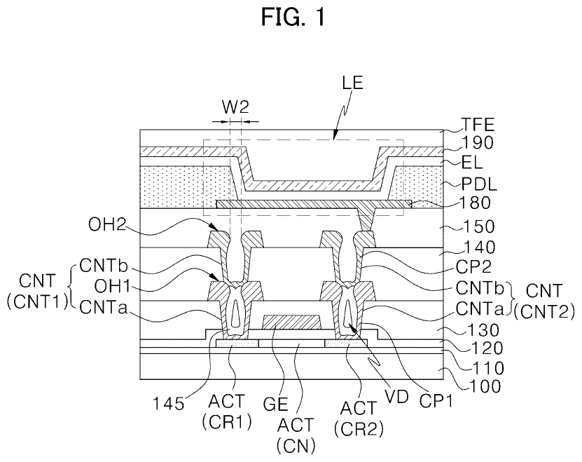

FIG. 1 is a schematic cross-sectional view of a display unit in a display panel DP or a display device DD including a thin film transistor according to embodiments.

Referring to FIG. 1, a transistor of a thin film transistor (TFT) type including an active layer ACT, may be disposed on a base substrate 100. According to embodiments, a plurality of the transistors may be arranged on the base substrate 100 to provide a display panel DP in the form of a TFT-array substrate and a display device DD including the display panel DP.

The display panel DP or the display device DD may include a light-emitting element LE connected to the transistor, and the light-emitting element LE may be connected to the transistor, such as through a contact electrode CNT.

The base substrate 100 may serve as a back-plane substrate of the display device DD or the display panel DP. A glass substrate or a plastic substrate may be used as the base substrate 100. The base substrate 100 may define a planar dimension of the display device DD or the display panel DP, without being limited thereto.

In some embodiments, the base substrate 100 may include a polymer material having transparency and flexibility. For example, the base substrate 100 may include a polymer material such as polyimide, polysiloxane, an epoxy resin, an acrylic resin, polyester, or the like. In an embodiment, the base substrate 100 may include polyimide.

In some embodiments, a glass substrate may be used as the base substrate 100.

A barrier layer 110 may be formed (or provided) on a top surface of the base substrate 100. Moisture penetrating through the base substrate 100 may be blocked by the barrier layer 110, and diffusion of impurities between the base substrate 100 and structures which are formed on the base substrate 100 may be blocked. The barrier layer 110 may cover the entire top surface of the base substrate 100.

The barrier layer 110 may include, e.g., an inorganic insulating material such as silicon oxide, silicon nitride, silicon oxynitride, or the like. These may be used alone or in combination thereof. In some embodiments, the barrier layer 110 may have a stacked structure including a silicon oxide layer and a silicon nitride layer. In some embodiments, the barrier layer 110 may include an organic layer, and may have a multi-layered structure of the organic layer and an inorganic layer.

The transistor may be disposed on the barrier layer 110. The transistor may include the active layer ACT and a gate electrode GE. A gate insulation layer 120 may be disposed between the active layer ACT and the gate electrode GE.

According to embodiments, the active layer ACT may include a silicon-based semiconductor (e.g., polysilicon or amorphous silicon). In an embodiment, the active layer ACT may include an oxide semiconductor such as indium gallium-zinc oxide (IGZO), zinc-tin oxide (ZTO), or ITZO.

The active layer ACT may include a channel region CN and contact regions CR1 and CR2. The contact regions CR1 and CR2 may have an increased electrical conductivity than that of the channel region CN. For example, the contact regions CR1 and CR2 may include the silicon-based semiconductor doped with a p-type or an n-type impurity. In some embodiments, the contact regions CR1 and CR2 may include a p-type impurity.

The contact regions CR1 and CR2 may include a first contact region CR1 and a second contact region CR2. A region between the first contact region CR1 and the second contact region CR2 may be defined as the channel region CN. For example, the first contact region CR1 and the second contact region CR2 may be formed at one side portion or the other side portion (e.g., opposing sides) of the active layer ACT, respectively.

The contact regions CR1 and CR2 may be provided as source/drain regions of the transistor. For example, the first contact region CR1 and the second contact region CR2 may be provided as a source region and a drain region, respectively.

The gate insulation layer 120 may be formed on the barrier layer 110 to cover the active layer ACT. The gate electrode GE may be disposed on the gate insulation layer 120. The gate electrode GE may substantially overlap the channel region CN in a thickness direction with the gate insulation layer 120 interposed therebetween. For example, a vertical direction in FIG. 1 may correspond to the thickness direction of the display panel DP or the display device DD.

The gate insulation layer 120 may include an inorganic insulating material such as silicon oxide, silicon nitride, silicon oxynitride, aluminum oxide, titanium oxide, tantalum oxide, hafnium oxide, or the like.

The gate electrode GE may include a metal such as tungsten (W), molybdenum (Mo), aluminum (Al), copper (Cu), titanium (Ti), tantalum (Ta), platinum (Pt), chromium (Cr), nickel (Ni), silver (Ag), or the like., or an alloy including at least one therefrom.

As illustrated in FIG. 1, the transistor may have a top-gate structure in which the gate electrode GE is disposed on the active layer ACT.

In an embodiment, the transistor may have a bottom-gate structure in which the gate electrode GE is disposed under the active layer ACT. In this case, the gate electrode GE may be disposed on the barrier layer 110, and the gate insulation layer 120 may cover the gate electrode GE. The active layer ACT may be disposed on the gate insulation layer 120 such that the channel region CN overlaps the gate electrode GE with the gate insulation layer 120 interposed therebetween.

Hereinafter, elements and structures of the transistor and the display device DD will be described based on embodiments including the top-gate structure.

A first insulating interlayer 130 may be formed on the gate insulation layer 120, to cover the gate electrode GE. The first insulating interlayer 130 may include an inorganic insulating material such as silicon oxide, silicon nitride, silicon oxynitride, aluminum oxide, titanium oxide, tantalum oxide, hafnium oxide, or the like. The first insulating interlayer 130 may have a single-layered structure or a multi-layered structure (e.g., a silicon oxide layer and a silicon nitride layer) including different materials.

The contact electrode CNT may be electrically connected to the contact regions CR1 and CR2. The contact electrode CNT may include a first contact electrode CNT1 and a second contact electrode CNT2 connected to or disposed on the first contact region CR1 and the second contact region CR2, respectively. In some embodiments, the first contact electrode CNT1 may serve as a source contact or a source electrode, and the second contact electrode CNT2 may serve as a drain contact or a drain electrode.

Each of the first and second contact electrodes CNT1 and CNT2 may include a lower contact CNTa as a lower contact electrode and an upper contact CNTb as an upper contact electrode. The lower contact CNTa may penetrate the first insulating interlayer 130 to be connected to or in contact with the contact regions CR1 and CR2. As used herein, elements which are in contact with each other may form an interface therebetween.

The lower contact CNTa may include a first overhang portion OH1 and a first contact portion CP1. The first overhang portion OH1 may refer to a portion of the lower contact CNTa formed on a top surface of the first insulating interlayer 130 which is adjacent to a respective contact hole thereof. According to embodiments, the first overhang portion OH1 may include a curved surface formed as a thickness or an overall size of the lower contact CNTa increases in a direction from the first contact portion CP1.

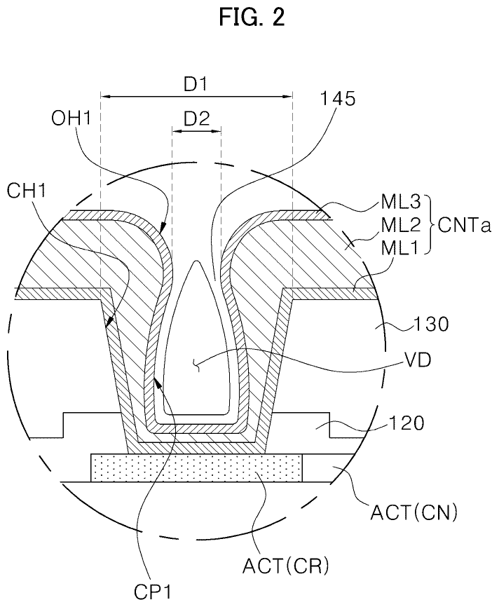

The first contact portion CP1 may be formed in a first contact hole CH1 (see FIG. 2) formed in the first insulating interlayer 130, to be in contact with or connected to the contact regions CR1 and CR2. In some embodiments, the first contact portion CP1 may penetrate the first insulating interlayer 130 and the gate insulation layer 120 to be in contact with or be connected to the contact regions CR1 and CR2 within the first contact hole CH1.

The first overhang portion OH1 may be integrally formed with the first contact portion CP1, and may have a shape extending from the first contact portion CP1 which is in the first contact hole CH1 to an outside of the first contact hole CH1. That is, the first overhang portion OH1 together with the first contact portion CP1 may be a single, continuous body. The first overhang portion OH1 may have a thickness greater than that of the first contact portion CP1. Here, the thickness of a layer may be defined in a direction normal to an underlying surface of an underlying layer along which the layer is provided.

A second insulating interlayer 140 may be formed on the first insulating interlayer 130 to cover the first overhang portion OH1 of the lower contact CNTa. The second insulating interlayer 140 may include an inorganic insulating material such as silicon oxide, silicon nitride, silicon oxynitride, aluminum oxide, titanium oxide, tantalum oxide, hafnium oxide, or the like. The second insulating interlayer 140 may have a single-layered structure or a multi-layered structure (e.g., a silicon oxide layer and a silicon nitride layer) including different materials.

The upper contact CNTb may be disposed directly on the lower contact CNTa. According to embodiments, when the lower contact CNTa is observed by a cross-section in a thickness direction as illustrated in FIG. 1, a pair of the first overhang portions OH1 may face each other in a direction along the base substrate 100. Accordingly, a first inlet (or recess) of the lower contact CNTa may be defined at the first overhang portions OH1 which are spaced apart from each other.

According to embodiments, the upper contact CNTb may close (or fill) the first inlet of the lower contact CNTa and may be disposed directly on the first overhang portion OH1. An insulating filler 145 may be formed in an inner space of the lower contact CNTa. The inner space may be closed by the upper contact CNTb.

The insulating filler 145 may include an inorganic insulating material substantially the same as or similar to that of the second insulating interlayer 140. A void VD may be included in the insulating filler 145. The void VD may be an empty space or gap defined within the insulating filler 145. The insulating filler 145 may be a discrete pattern within the recess of the lower contact CNTa. Here, the upper contact CNTb may be between the insulating filler 145 and the second insulating interlayer 140. In an embodiment, the void VD may be surrounded or enclosed by the insulating filler 145 such that the void VD does not expose the lower contact CNTa.

The upper contact CNTb may include a second overhang portion OH2 and a second contact portion CP2. The second overhang portion OH2 may refer to a portion of the upper contact CNTb formed on a top surface of the second insulating interlayer 140. The second contact portion CP2 may be in the second insulating interlayer 140 to be in contact with the lower contact CNTa at the first overhang portion OH1 thereof. According to embodiments, the second contact portion CP2 may be in direct contact with the curved surface of the first overhang portion OH1.

The second overhang portion OH2 may be integrally formed with the second contact portion CP2, and may have a shape extending from the second contact portion CP2. The second overhang portion OH2 may have a thickness greater than that of the second contact portion CP2. The second overhang portion OH2 may include a curved surface formed as a thickness or an overall size increases in a direction away from the second contact portion CP2.

A bottom portion of the second contact portion CP2 may be in contact with an upper portion the first overhang portion OH1 of the lower contact CNTa. The bottom portion of the second contact portion CP2 may be in contact with a pair of the first overhang portions OH1 facing each other in the cross-section of the lower contact CNTa. The bottom portion of the second contact portion CP2 may also be in contact with the insulating filler 145.

A planarization layer 150 covering the upper contact CNTb may be formed on the second insulating interlayer 140. The planarization layer 150 may include an organic material such as polyimide, an epoxy resin, an acrylic resin, polyester, a siloxane resin, a benzocyclobutene (BCB), or the like.

The planarization layer 150 may fill an inner space (or recess) of the upper contact CNTb. For example, the inner space of the upper contact CNTb may be filled through a second inlet defined by second overhang portions OH2 facing each other in the cross-section of the upper contact CNTb.

A display element of a display unit which is electrically connected to the transistor through the contact electrodes CNT1 and CNT2 may be disposed on the planarization layer 150. The display element may include a light-emitting element LE.

The light-emitting element LE may include a first electrode 180, a light-emitting portion EL and a second electrode 190.

The first electrode 180 may be disposed on the planarization layer 150, and may include a via electrode which may penetrate the planarization layer 150 to be in contact with or connected to the contact electrode CNT. The via electrode may be in contact with the second overhang portion OH2 of the upper contact CNTb in the planarization layer 150.

The first electrode 180 may serve as a pixel electrode or an anode, and may include a high work function (electrically) conductive material which may promote hole injection. The first electrode 180 may be formed as a transmissive electrode. The first electrode 180 may include a transparent conductive oxide such as indium tin oxide (ITO), indium zinc oxide (IZO), zinc oxide (ZnO), indium tin oxide (ITZO), or the like.

The first electrode 180 may be formed as a translucent electrode or a reflective electrode. The first electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy containing two or more therefrom.

The first electrode 180 may have a single-layered structure or a multi-layered structure. For example, the first electrode 180 may have a tiple-layered structure of ITO/Ag/ITO.

A pixel defining layer PDL may be formed on the planarization layer 150 to at least partially expose a top surface of the first electrode 180. A solid (material) portion of the pixel defining layer PDL may cover a peripheral portion of the first electrode 180 and have a pixel opening defined therein to expose the first electrode 180 to an outside of the pixel defining layer PDL.

A light-emitting region may be defined by a sidewall of the pixel defining layer PDL which defines the pixel opening. For example, a green light-emitting region, a blue light-emitting region and a red light-emitting region may be separated and defined by the pixel defining layer PDL. Here, a dimension (e.g., a planar area) of the light-emitting region may correspond to a dimension of the pixel opening. In an embodiment, a planar area of the light-emitting region may be defined along a first (horizontal) direction and a second (into the page) direction of FIG. 1, which cross each other. Here, a plane may be defined along the first and second directions crossing each other.

The pixel defining layer PDL may include, e.g., an organic material such as a polysiloxane resin, a polyimide resin, an acrylic resin, or the like. The pixel defining layer PDL may include a colorant such as a black pigment/dye dispersed in the resin material.

The light-emitting portion EL may be disposed on the first electrode 180 and the pixel defining layer PDL. The light-emitting portion EL may include an organic emission layer independently patterned for each of a red pixel, a green pixel and a blue pixel to generate a different colored light for each of the pixels.

In an embodiment, the light-emitting portion EL may continuously and commonly extend throughout a plurality of the pixels PX. In this case, the light-emitting portion EL may include a white emission layer. In an embodiment, the light-emitting portion EL may include emission layers corresponding to a plurality of different colored light or the same colored light, and may have a stack of a tandem structure.

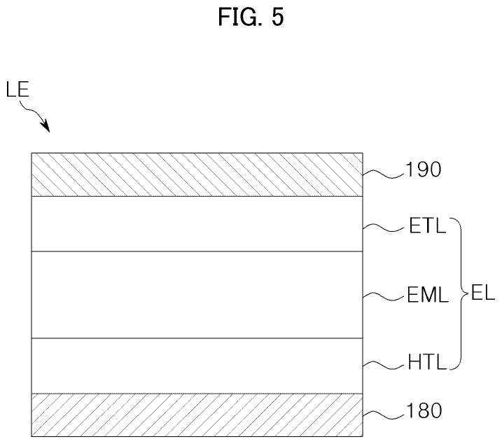

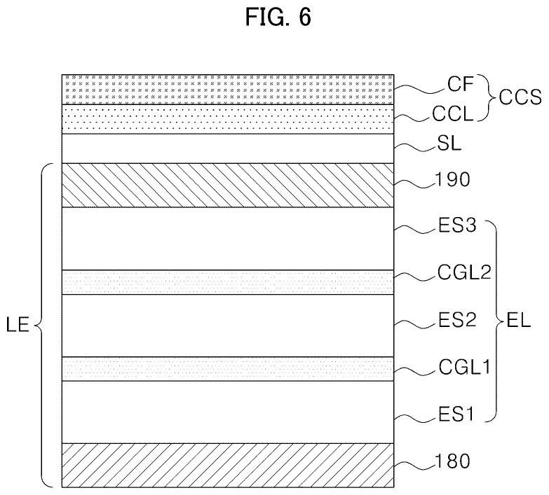

A construction the light-emitting element LE including the light-emitting portion EL will be described in more detail later with reference to FIGS. 5 and 6.

The second electrode 190 may be disposed on the light-emitting portion EL. The second electrode 190 may be a common electrode continuously and commonly provided in a plurality of the light-emitting regions or the pixels PX.

The second electrode 190 may serve as an electron injection electrode or a cathode. The second electrode 190 may include a metal, an alloy, an electrically conductive compound, or the like, having a low work function.

For example, the second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-yterbium (Ag—Yb), ITO, IZO, or the like. These may be used alone or in a combination thereof.

The second electrode 190 may be formed as a transmissive electrode, a translucent electrode or a reflective electrode. The second electrode 190 may have a single-layered structure or a multi-layered structure.

The light-emitting element LE may be defined by the first electrode 180, the light-emitting portion EL, and the second electrode 190 as described above. The light-emitting element LE may be provided as an organic light-emitting diode (OLED) element.

An encapsulation layer TFE may be formed on the second electrode 190. The encapsulation layer TFE may be disposed on the pixel defining layer PDL and the light-emitting elements to protect the light-emitting elements from moisture or oxygen.

The encapsulation layer TFE may include an inorganic layer including silicon nitride (SiNx), silicon oxide (SiOx), indium tin oxide, indium zinc oxide, or any combination thereof, an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE), or a combination thereof, or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer, and a second inorganic layer.

In some embodiments, a color control structure overlapping the light-emitting portion EL may be disposed on the encapsulation layer TFE. The color control structure may include a color conversion layer including quantum dots and/or a color filter.

FIG. 2 is a partially enlarged cross-sectional view of a lower contact CNTa and structures adjacent to the lower contact CNTa of FIG. 1. For convenience of descriptions, illustration of the upper contact are omitted in FIG. 2.

Referring to FIG. 2, the lower contact cnta may have a stacked structure of a

plurality of conductive layers. For example, the lower contact CNTa may have a stacked structure of a plurality of metal layers. The lower contact CNTa may include a first metal layer ML1, a second metal layer ML2 and a third metal layer ML3 sequentially stacked from a top (underlying) surface of the first insulating interlayer 130, an inner wall of layers which form the first contact hole CH1, and/or a top surface of the contact region CR.

The first metal layer ML1 and the third metal layer ML3 may include a metal which may be more stable to oxidation or corrosion than that of the second metal layer ML2. The first metal layer ML1 and the third metal layer ML3 may include the same metal. The first metal layer ML1 and the third metal layer ML3 may include a metal having improved interfacial adhesion properties than that of the second metal layer ML2. The second metal layer ML2 may include a metal having a lower electrical resistance than that of the first metal layer ML1 and the third metal layer ML3.

In an embodiment, the first metal layer ML1, the second metal layer ML2 and the third metal layer ML3 may be in order and include a Ti-layer, an Al-layer and a Ti-layer, respectively. A thickness of the second metal layer ML2 may be greater than a thickness of each of the first metal layer ML1 and the third metal layer ML3.

For example, a maximum thickness of the second metal layer ML2 may be in a range from about 1,000 angstroms (Å) to about 10,000 Å, from about 3,000 Å to about 8,000 Å, or from about 4,000 Å to about 7,000 Å. A maximum thickness of each of the first metal layer ML1 and the third metal layer ML3 may be in a range from about 100 Å to about 800 Å, from about 200 Å to about 700 Å, or from about 300 Å to about 600 Å.

As described above, the insulating filler 145 may be formed in the inner space of the lower contact CNTa, and the void VD may be included in the insulating filler 145. The first inlet of the lower contact CNTa may be defined between inner surfaces at the first overhang portions OH1 which face each other in the cross-section of the lower contact CNTa. In FIG. 2, a width of the first inlet is indicated as D2.

A width of the first contact hole CH1 in which the lower contact CNTa is formed may be indicated as D1. The width D1 of the first contact hole CH1 may be an uppermost diameter (or a maximum dimension) of the first contact hole CH1 which may be defined by an edge of an top surface of the first insulating interlayer 130 in which the first contact hole CH1 is formed.

In some embodiments, the width D2 of the first inlet may be equal to or less than about 50% of the width D1 of the first contact hole CH1. In an embodiment, the width D2 of the first inlet may be in a range from about 10% to about 50%, from about 20% to about 45%, from about 20% to about 40%, from about 30% to about 45%, or from about 30% to about 40%, of the width D1 of the first contact hole CH1.

In some embodiments, a width W2 (see FIG. 1) of a second inlet defined between a pair of the second overhang portions OH2 facing each other in the cross-section of the upper contact CNTa may be greater than or equal to the width D2 of the first inlet. In an embodiment, the width W2 (see FIG. 1) of the second inlet may be greater than the width D2 of the first inlet.

Accordingly, as illustrated in FIG. 1, the inner space of the upper contact CNTb may be completely filled with the planarization layer 150 without generating voids.

According to the above-described embodiments of the present disclosure, a high aspect ratio contact electrode included in a high-resolution display device such as a virtual reality glass (GVR) may be divided into a multi-layered structure.

As the aspect ratio of the contact hole increases, a width of the contact hole may be relatively decreased. Accordingly, due to, e.g., limitation of a step coverage in a material deposition process for forming the contact electrode, the second metal layer ML2 may not be sufficiently filled into the contact hole to result in a void in the contact electrode.

Response properties of the display device DD may be deteriorated due to an increase in resistance of the contact electrode caused by the void. Further, mechanical defects such as collapse and disconnection of the contact electrode may occur.

However, according to embodiments, an aspect ratio of each contact electrode may be reduced by dividing the contact electrode CNT into the lower contact CNTa and the upper contact CNTb. Accordingly, a size of the void VD may be reduced, and the void VD may be limited in the insulating filler 145. Thus, disconnection or discontinuity of the metal layers ML1, ML2 and ML3 included in the lower contact CNTa caused when the void VD is expanded to the lower contact CNTa may be prevented.

Further, the first overhang portions OH1 of the lower contact CNTa may be used as a landing pad of a material for forming the upper contact CNTb. A direct contact area of the upper contact CNTb relative to the lower contact CNTa may be increased by the first overhang portions OH1, and a sufficient electrical signal speed may be obtained. The upper contact CNTb may close the opening (a first opening) of the lower contact CNTa, and may further increase a conductive region, that is, the contact area at which the upper contact CNTb electrically contacts the lower contact CNTa.

In an embodiment, a display device DD (or a display panel DP) includes a light-emitting element LE, a transistor connected to the light-emitting element LE, the transistor including an active layer ACT including a contact region CR and a channel region CN and a gate electrode GE overlapping the channel region CN of the active layer ACT, an insulating layer (120, 130 and 140, for example) which is between the active layer ACT and the light-emitting element LE and in which a contact hole (CH1 and CH2, for example) is defined exposing the contact region CR of the active layer ACT to an outside of the insulating layer, and a contact electrode CNT electrically connecting the light-emitting element LE to the transistor, at the contact region CR of the active layer ACT which is exposed to an outside of the insulating layer, the contact electrode including a lower contact CNTa including a first contact portion CP1 which is in the contact hole, and at which the lower contact CNTa is connected to the contact region CR of the active layer ACT, and a first overhang portion OH1 which extends from the first contact portion CP1, in a direction away from the contact hole, and has a curved surface, and an upper contact CNTb which is in the contact hole, and directly contacts the lower contact CNTa at the curved surface of the first overhang portion OH1.

The first contact portion CP1 may define a first recess (e.g. a first recess RS1 as illustrated in FIG. 9) of the lower contact CNTa which is open at a first inlet of the lower contact CNTa, the first inlet being defined by the first overhang portion OH1 and having a width, the contact hole has a first width corresponding the first contact portion CP1 of the lower contact CNTa, and the width of the first inlet is smaller than the first width of the contact hole.

The first inlet and the first recess of the lower contact CNTa may be closed by the upper contact CNTb. Here, the insulating filler 145 may be in the first recess which is closed by the upper contact CNTb. The insulating filler 145 may have the void VD defined therein, such that the void VD is surrounded by the insulating filler 145.

The insulating layer may include a first insulating interlayer 130 covering the active layer ACT and the gate electrode GE, the first insulating interlayer 130 including a first contact hole CH1 defined therein which exposes the contact region CR of the active layer ACT and has the first width, and a second insulating interlayer 140 on the first insulating interlayer 130, the second insulating interlayer 140 including a second contact hole CH2 defined therein which exposes the first overhang portion OH1 of the lower contact CNTa to an outside of the second insulating interlayer 140.

The upper contact CNTb may include a second contact portion CP2 which is in the second contact hole CH2, at which the upper contact CNTb contacts the first overhang portion OH1, and covers the first inlet of the lower contact CNTa, and a second overhang portion OH2 which extends from the second contact portion CP2, in a direction away from the second contact hole CH2, and is at an outside of the second contact hole CH2.

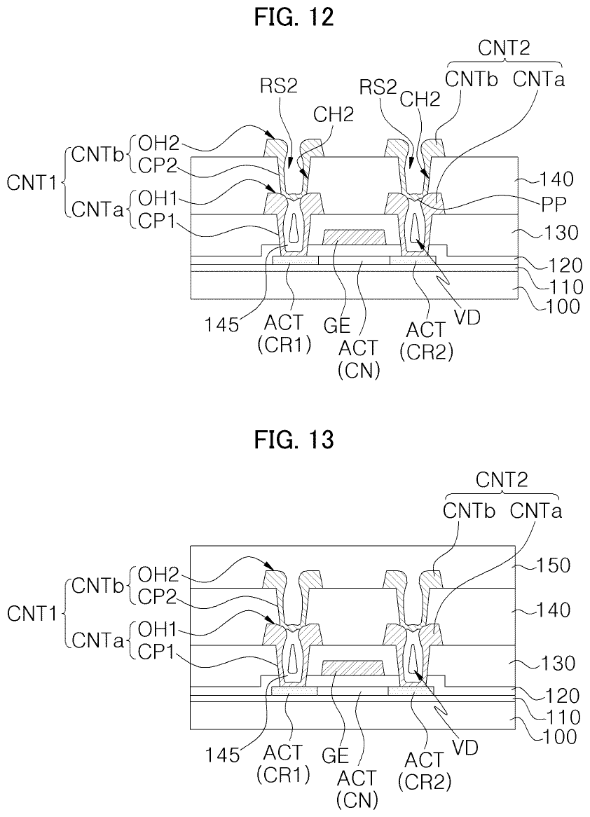

The second contact portion CP2 may define a second recess (e.g., a second recess RS2 as illustrated in FIG. 12) of the upper contact CNTb which is open at a second inlet of the upper contact CNTb, the second inlet being defined by the second overhang portion OH2 and having a width. The contact hole has a second width corresponding to the second contact portion CP2 of the upper contact CNTb, the width of the second inlet being smaller than the second width of the second contact hole CH2, and greater than or equal to the width of the first inlet of the lower contact CNTa.

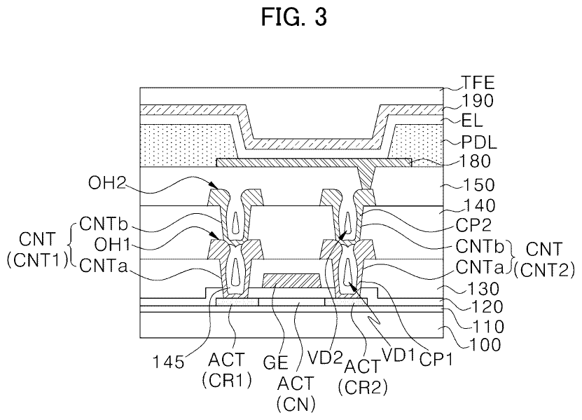

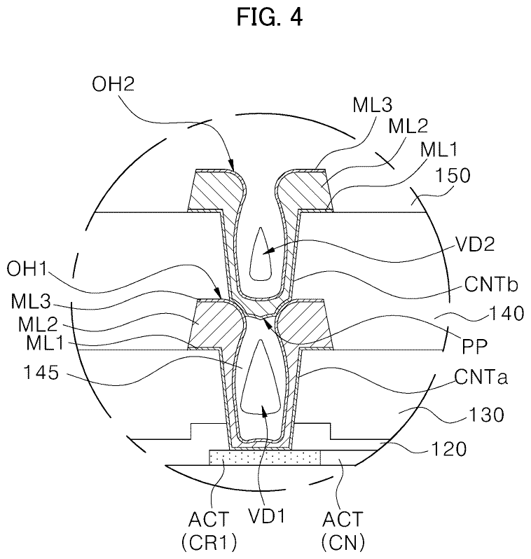

FIG. 3 is a schematic cross-sectional view of a display unit in a display panel DP or a display device DD including a thin film transistor according to embodiments. FIG. 4 is a partially enlarged cross-sectional view of a stacked structure of a lower contact CNTa and an upper contact CNTb of FIG. 3. Detailed descriptions on elements and structures substantially the same as or similar to those described with reference to FIGS. 1 and 2 are omitted.

Referring to FIG. 3, a void may also be formed in a portion of the planarization layer 150 filling a remainder of an inner space (or recess) of the upper contact CNTb of the contact electrode CNT. According to embodiments, a first void VD1 may be included in the insulating filler 145 formed in the inner space of the lower contact CNTa, and a second void VD2 may be included in a portion of the planarization layer 150 filling the inner space of the upper contact CNTb. The planarization layer 150 which is on the second insulating interlayer 140 may extend into the second recess of the upper contact CNTb to fill the second recess. The planarization layer 150 which is in the second recess may include a second void VD2 defined therein.

In some embodiments, a size (a volume or a cross-sectional area) of the second void VD2 may be smaller than a size of the first void VD1. As described above, the width W2 of the second inlet of the upper contact CNTb may be greater than the width D2 of the first inlet of the lower contact CNTa. Accordingly, a flow of the material of the planarization layer 150 to the second inlet may be relatively promoted, and the size of the second void VD2 may be reduced.

Referring to FIG. 4, the upper contact CNTb may also include a stacked structure of the first metal layer ML1, the second metal layer ML2, and the third metal layer ML3 which may be substantially the same as or similar to that of the lower contact CNTb.

A bottom portion of the upper contact CNTb may completely close the first inlet of the lower contact CNTb. In some embodiments, the bottom portion of the upper contact CNTb may include a tip portion PP protruding toward a bottom of the lower contact CNTa or the first contact hole CH1. A lower end of the upper contact CNTb may seal the first inlet at the lower contact CNTa.

An area (e.g., a planar area) in which the bottom of the upper contact CNTb contacts the first overhang portion OH1 of the lower contact CNTa may be increased by the formation of the tip portion PP. Thus, an overall (electrical) resistance of the contact electrode CNT may be reduced while reducing a contact (electrical) resistance between the lower contact CNTa and the upper contact CNTb.

FIGS. 5 and 6 are schematic cross-sectional views illustrating light-emitting elements LE according to embodiments.

Referring to FIG. 5, as described above, the light-emitting element LE may include the first electrode 180 and the second electrode 190, and the light-emitting portion EL as a light-emitting disposed between the first electrode 180 and the second electrode 190.

The light-emitting portion EL may include a hole transport layer HTL, an emission layer EML, and an electron transport layer ETL. According to embodiments, the hole transport layer HTL, the emission layer EML, the electron transport layer ETL, and the second electrode 190 may be sequentially stacked from a top surface of the first electrode 180.

The emission layer EML may include an organic light-emitting material having red, green, or blue emission properties. For example, the emission layer EML may include a fluorescent host and/or a host for a phosphorescent device, and may further include a fluorescent dopant, a phosphorescent dopant, and/or a thermally activated delayed fluorescence (TADF) dopant.

For example, hole transport layer HTL may include a hole transporting material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, electron transport layer ETL may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the first electrode 180 and the hole transport layer HTL. An electron injection layer may be further disposed between the second electrode 190 and the electron transport layer ETL.

Referring to FIG. 6, the light-emitting portion EL may include a plurality of light-emitting structures ES1, ES2 and ES3. Each of the light-emitting structures ES1, ES2, and ES3 may include a hole transport layer HTL, an emission layer EML and an electron transport layer ETL. According to embodiments, the light-emitting element LE of FIG. 6 may be a light-emitting element having a tandem structure which generates a white light or a blue light.

Charge generation layers CGL1 and CGL2 may be disposed between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 between a first light-emitting structure ES1 and a second light-emitting structure ES2, and a second charge generation layer CGL2 between the second light-emitting structure ES2 and a third light-emitting structure ES3.

According to embodiments, the first light-emitting structure ES1, the first charge generation layer CGL1, the second light-emitting structure ES2, the second charge generation layer CGL2, the third light-emitting structure ES3 and the second electrode 190 may be sequentially stacked from the top surface of the first electrode 180.

In some embodiments, a color control structure CCS overlapping the light-emitting portion EL may be disposed on the second electrode 190. The color control structure CCS may include a color control layer CCL and a color filter CF. The color control layer CCL may include quantum dots which convert a white light or a blue light into another color light (e.g., a red light or a green light). In this case, the display device may be implemented in the form of a quantum dot-organic light-emitting diode (QD-OLED) device.

The color control structure CCS may be coupled to the light-emitting element LE by a sealing layer SL. The sealing layer SL may be formed on the encapsulation layer TFE.

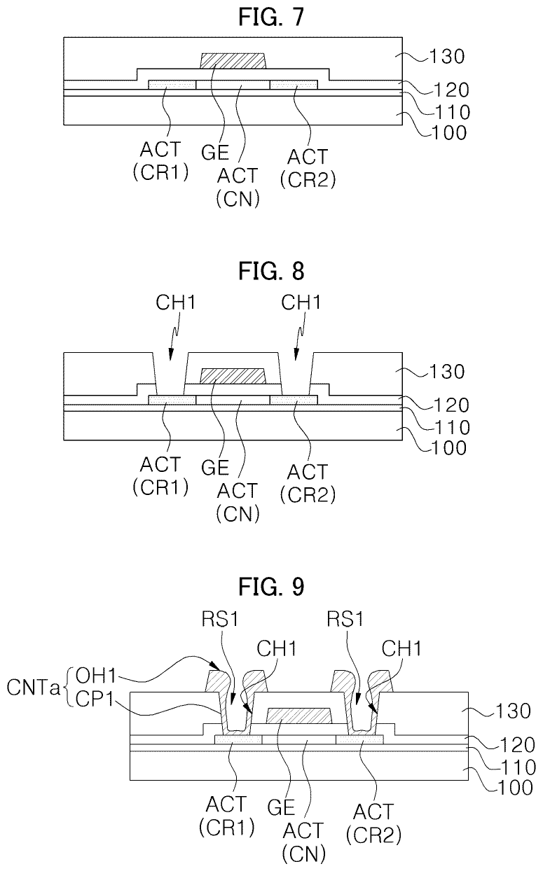

FIGS. 7 to 13 are schematic cross-sectional views illustrating a method of manufacturing (or providing) a display panel DP or a display device DD according to embodiments. Detailed descriptions of the materials described with reference to FIG. 1 are omitted.

Referring to FIG. 7, the barrier layer 110 may be formed (or provided) on the base substrate 100, and the active layer ACT may be formed on the barrier layer 110.

The barrier layer 110 may be formed by a deposition process such as a chemical vapor deposition (CVD) process, a sputtering process, an atomic layer deposition (ALD) process, or the like, to include the above-mentioned inorganic insulating material.

For example, an amorphous silicon layer may be formed on a top surface of the barrier layer 110 and then heat-treated to form a silicon layer. The silicon layer may be patterned through a photo-lithography process to form the active layer ACT. In an embodiment, the active layer ACT may be formed of a low-temperature polysilicon (LTPS) layer.

Thereafter, the gate insulation layer 120 covering the active layer ACT may be formed on the barrier layer 110. The gate insulation layer 120 may be formed by a deposition process such as a CVD process to include the above-mentioned inorganic insulating material.

The gate electrode GE overlapping a portion of the active layer ACT may be formed on the gate insulation layer 120. A conductive material layer including the above-mentioned metal may be formed by a deposition process such as a sputtering process. The conductive material layer may be pattered by a photo-lithography etching process to form the gate electrode GE.

According to embodiments, an impurity doping process using the gate electrode GE as an ion implantation mask may be performed. In an embodiment, p-type impurities may be doped at opposing sides of the active layer ACT by the ion implantation process or the impurity doping process.

Thus, electrical conductivity of both side portions of the active layer ACT may be increased to form the first contact region CR1 and the second contact region CR2. A portion of the active layer ACT between the first contact region CR1 and the second contact region CR2 substantially overlapping the gate electrode GE may be defined as the channel region CN.

Thereafter, the first insulating interlayer 130 covering the gate electrode GE may be formed on the gate insulation layer 120. The first insulating interlayer 130 may be formed by a deposition process such as a CVD process to include the above-mentioned inorganic insulating material. One or both of the gate insulation layer 120 and the first insulating interlayer may be referred to as an insulating layer.

Referring to FIG. 8, the first contact hole CH1 exposing each of the first contact region CR1 and the second contact region CR2 to an outside of the insulating layer, may be formed in the insulating layer.

According to embodiments, the first insulating interlayer 130 and the gate insulation layer 120 may be sequentially etched by an anisotropic etching process such as a dry etching process to form the first contact hole CH1.

Referring to FIG. 9, the lower contact CNTa which may be in contact with or electrically connected to the first contact region CR1 and the second contact region CR2 may be formed in each of the first contact hole CH1. The lower contact CNTa may have a first recess RS1 defined therein which overlaps the first contact hole CH1. The first recess may be open in a direction away from the insulating layer.

According to embodiments, the first metal layer ML1, the second metal layer ML2 and the third metal layer ML3 may be sequentially formed along a top surface of the first insulating interlayer 130, and an inner wall and a bottom surface of the insulating layer which define a profile of the first contact hole CH1.

Thereafter, the third metal layer ML3, the second metal layer ML2 and the first metal layer ML1 may be partially etched to form the lower contact CNTa which may partially fill a volume of the first recess at the first contact hole CH1, and have the first overhang portion OH1 protruding above the top surface of the first insulating interlayer 130. A portion of the lower contact CNTa formed on the inner wall and the bottom surface of the first contact hole CH1 may be defined as the first contact portion CP1.

A first inlet of the lower contact CNTa having a width smaller than a width of the first contact hole CH1 may be defined by the first overhang portion OH1.

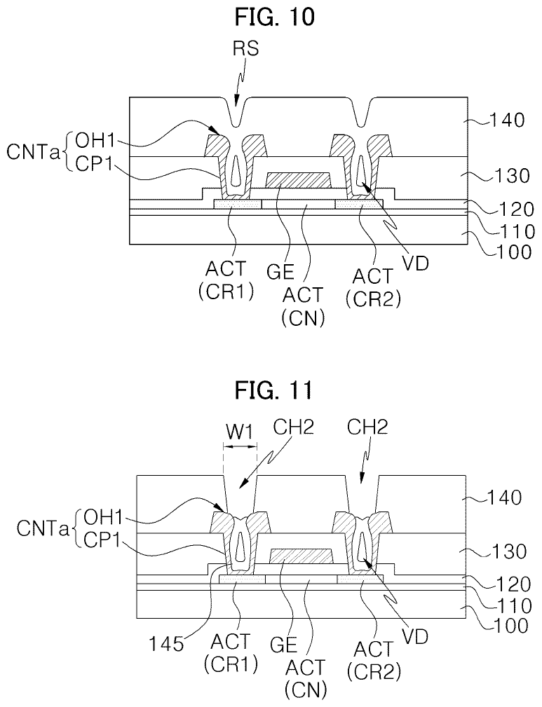

Referring to FIG. 10, the second insulating interlayer 140 covering the lower contact CNTa may be formed on the first insulating interlayer 130. The second insulating interlayer 140 may be formed by a deposition process such as a CVD process to include the above-mentioned inorganic insulating material.

The second insulating interlayer 140 may fill an inner space of the lower contact CNTa, through the first inlet of the lower contact CNTa. According to embodiments, the second insulating interlayer 140 may partially fill an inner space of the lower contact CNTa to generate the void VD within the second insulating interlayer 140.

A recess RS may be formed at a portion of the second insulating interlayer 140 which overlaps the first overhang portion OH1 or the first inlet of the lower contact CNTa.

Referring to FIG. 11, the second insulating interlayer 140 may be partially etched at a location corresponding to the inlet of the lower contact CNTa, to form a second contact hole CH2 in the second insulating interlayer 140 which exposes the first overhang portion OH1 of the lower contact CNTa.

According to embodiments, a thickness portion of the second insulating interlayer 140 at the recess RS illustrated in FIG. 10 may be removed by the etching process to form the second contact hole CH2. The first overhang portion OH1 may be partially exposed to an outside of the second insulating interlayer 140 by the second contact hole CH2. According to embodiments, a pair of the first overhang portions OH1 facing each other in a cross-section of the lower contact CNTa may be exposed together by the second contact hole CH2. A portion of the first overhang portions OH1 which are adjacent (or closest) to the inlet of the lower contact CNTa are exposed at the second contact hole ch2.

A remaining portion of the second insulating interlayer 140 may be separated from a portion thereof which is formed in the inner space of the lower contact CNTa by the exposed surface of the first overhang portion OH1 in the etching process. Accordingly, the insulating filler 145 generated from the second insulating interlayer 140 may be formed in the inner space of the lower contact CNTa. Here, the insulating filler 145 and the second insulating interlayer 140 may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

A width of the second contact hole CH2 may be indicated as W1 (e.g., a first width). The width of the second contact hole CH2 may correspond to a diameter of an uppermost portion of the second contact hole CH2 defined by an edge of the second insulating interlayer 140. One or more of the gate insulation layer 120, the first insulating interlayer 130 and the second insulating interlayer 140 may be considered as an insulating layer, and one or more for the first contact hole CH1 and the second contact hole CH2 may be considered as a contact hole in the insulating layer.

Referring to FIG. 12, the upper contact CNTb contacting the lower contact CNTa may be formed in the second contact hole CH2. The upper contact CNTb may have a second recess RS2 defined therein which overlaps the second contact hole CH2. The second recess may be open in a direction away from the insulating layer.

According to embodiments, the first metal layer ML1, the second metal layer ML2 and the third metal layer ML3 may be sequentially formed along a top surface of the second insulating interlayer 140, a sidewall of the insulating layer at the second contact hole CH2, the exposed surface of the first overhang portion OH1, and the exposed surface of the insulating filler 145.

Thereafter, the third metal layer ML3, the second metal layer ML2 and the first metal layer ML1 may be partially etched to form the upper contact CNTb which may partially fill the second contact hole CH2 and having the second overhang portion OH2 which protrudes above the top surface of the second insulating interlayer 140. A second inlet having the width W2 (see FIG. 1, e.g., a second width) smaller than the width W1 of the second contact hole CH2 may be defined by the second overhang portion OH2.

A portion of the upper contact CNTb which is formed in the second contact hole CH2 to be in contact with the lower contact CNTa may be defined as the second contact portion CP2. The second contact portion CP2 may include the tip portion PP protruding toward a bottom surface of the lower contact CNTa.

As the upper contact CNTb is formed, the first contact electrode CNT1 and the second contact electrode CNT2 including the lower contact CNTa and the upper contact CNTb which may be in direct contact by the first overhang portion OH1 may be obtained.

Referring to FIG. 13, the planarization layer 150 covering the upper contact CNTb may be formed on the second insulating interlayer 140. The planarization layer 150 may be formed by a coating process, e.g., a spin coating process, to include the above-mentioned organic insulating material.

The planarization layer 150 may fill an inner space of the upper contact CNTb, through the second inlet. As described above, the second inlet may have a width greater than that of the first inlet, and a void may not be substantially formed in a portion of the planarization layer 150 in the inner space of the upper contact CNTb.

In some embodiments, as described with reference to FIGS. 3 and 4, the second void VD2 having a size smaller than that of the first void VD1 formed in the insulating filler 145 may be formed in the portion of the planarization layer 150 formed in the inner space of the upper contact CNTb.

Referring again to FIG. 1, the planarization layer 150 may be partially etched to form a via hole exposing, e.g., a top surface of the second overhang portion OH2 of the second contact electrode CNT2. The first electrode 180 filling the via hole may be formed on the planarization layer 150.

The pixel defining layer PDL may be formed on the planarization layer 150. The pixel defining layer PDL may cover a peripheral portion of the first electrode 180. In an embodiment, the pixel defining layer PDL may be formed by exposure and development processes after coating a photosensitive organic material such as a polysiloxane resin, a polyimide resin, an acrylic resin, or the like. In an embodiment, the pixel defining layer PDL may be formed by a printing process such as an inkjet printing process using a polymer material or an inorganic material.

The light-emitting portion EL may be formed on a top surface of the first electrode 180 exposed through the pixel defining layer PDL, and a sidewall of the pixel defining layer PDL.

The light-emitting portion EL may be formed by a thermal deposition, a vaporization deposition, a vacuum deposition, a spin coating, an inkjet printing, a laser printing, a casting, a laser thermal transfer, or the like, to include the above-mentioned organic light-emitting material.

As described with reference to FIG. 5, the light-emitting portion EL may include the hole transport layer HTL, the emission EML and the electron transport layer ETL.

In some embodiments, the hole transport layer HTL and the electron transport layer ETL may be continuously and commonly formed throughout a plurality of pixels PX or the first electrodes 180 and a surface of the pixel defining layer PDL. In some embodiments, the emission layer EML may be selectively patterned for each first electrode 180 of an individual pixel.

The second electrode 190 serving as a common electrode may be formed on the pixel defining layer PDL and the light-emitting portion EL, and then the encapsulation layer TFE protecting the pixels and the second electrode 190 may be formed. The encapsulation layer TFE may be formed to include a multi-layered structure of an inorganic insulating layer and an organic insulating layer. For example, the encapsulation layer TFE may be formed in a sequential stacked structure of a first inorganic insulating layer, an organic insulating layer and a second inorganic insulating layer.

In an embodiment, a method of providing a display device DD or display panel DP includes providing a transistor including an active layer ACT and a gate electrode GE which overlaps the active layer ACT, on a base substrate 100, providing a contact electrode CNT which electrically connects the transistor to a light-emitting element LE, where the providing of the contact electrode CNT includes providing a first insulating interlayer 130 covering the gate electrode GE of the transistor, etching the first insulating interlayer 130 to provide a first contact hole CH1 which is in the first insulating interlayer 130 and exposes the active layer ACT to an outside of the first insulating interlayer 130, providing a lower contact CNTa of the contact electrode CNT, the lower contact CNTa including a first contact portion CP1 which is in the first contact hole CH1, defines a first recess of the lower contact CNTa, and at which the lower contact CNTa is connected to the active layer ACT, and a first overhang portion OH1 which extends from the first contact portion CP1 and to an outside of the first contact hole CH1, providing a second insulating interlayer 140 on the first insulating interlayer 130, extending into the first recess of the lower contact CNTa, and covering the lower contact CNTa, etching the second insulating interlayer 140 to provide a second contact hole CH2 which is in the second insulating interlayer 140, and exposes the first overhang portion OH1 of the lower contact CNTa to an outside of the second insulating interlayer 140, the etching of the second insulating interlayer 140 separating a portion of the second insulating interlayer 140 which is in the first recess from a remainder of the second insulating interlayer 140, providing an upper contact CNTb of the contact electrode CNT which is in the second contact hole CH2 and contacts the lower contact CNTb at the first overhang portion OH1 of the lower contact CNTa.

The providing of the second insulating interlayer 140 may form a void VD in the portion of the second insulating interlayer 140 which is in the first recess. The portion of the second insulating interlayer 140 (e.g., the insulating filler 15) fills the first recess.

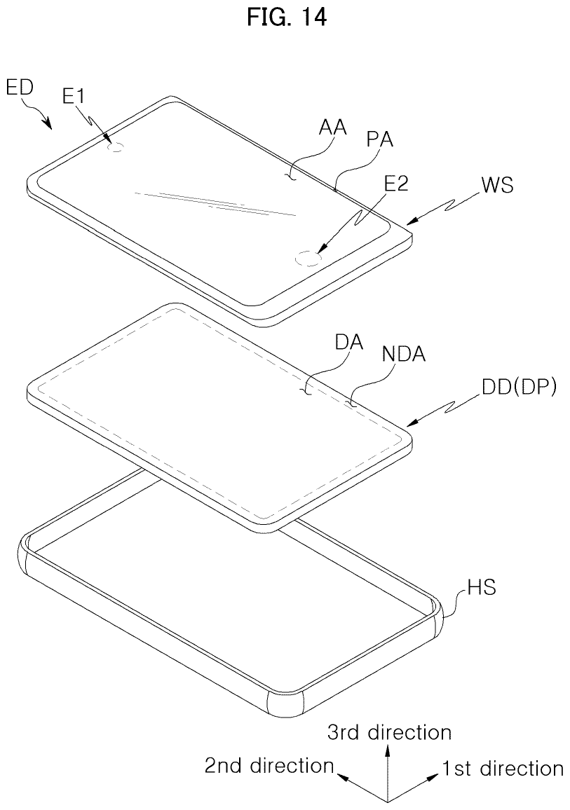

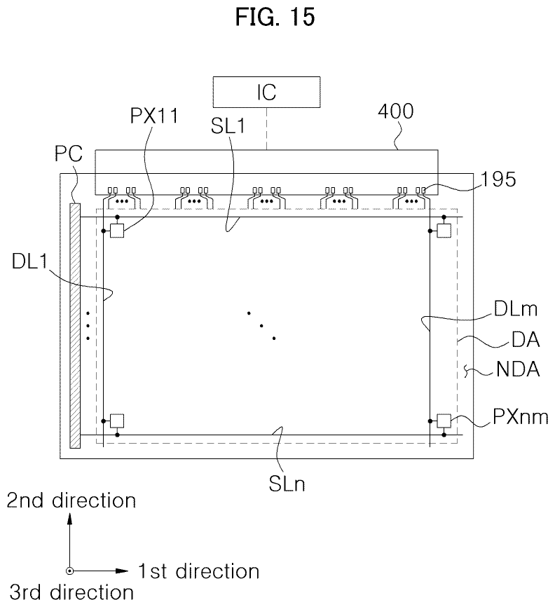

FIG. 14 is an exploded perspective view illustrating an electronic device ED according to embodiments. FIG. 15 is a schematic plan view illustrating arrangement of pixels PX of a display device DD included in an electronic device ED according to embodiments.

In FIGS. 14 and 15, a first direction and a second direction may refer to two directions parallel to a window structure WS and/or a display surface of a display panel DP. The two directions may be perpendicular to each other. For example, the first direction may correspond to an X-direction (a row direction) of a display device DD or the display panel DP, and the second direction may correspond to a Y-direction (a column direction) of the display device DD or the display panel DP. A plane may be defined by the first and second directions intersecting each other. A thickness of the display panel DP (or the display device DD or the electronic device ED), and various components or layers thereof, may be defined along a third direction crossing the first and second directions (e.g., a thickness direction).

According to embodiments, the electronic device ED may be implemented in the form of a mobile phone (smart phone), a tablet, a PC, or the like, including the above-described display device DD.

Referring to FIG. 14, the electronic device ED may include the window structure WS, the display device DD and a housing HS. The display device DD may include the display panel DP including the transistors and the light-emitting element LE as described above. The housing HS, the display device DD, and the window structure WS may be sequentially stacked in the third direction.

The window structure WS may provide an external display surface recognized from an outside of the electronic device ED by a user, such as a viewing surface of an electronic device ED, e.g., a mobile phone, and may include a transparent material film. For example, the window structure WS may include glass (e.g., ultra-thin glass (UTG)), a hard coating film, a plastic film, or the like.

An outer surface of the window structure WS may include an active area AA and a peripheral area PA which is adjacent to and extended along the active area AA. The active area AA may provide a surface from which an image of the display device DD is substantially displayed and to which a user's touch/command is input. The peripheral area PA may substantially correspond to a bezel area of the display device DD. The bezel area may correspond to an area at which an image is not displayed, without being limited thereto.

The display device DD and the display panel DP may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS. An image may not be displayed at the non-display area NDA.

In some embodiments, functional device areas E1 and E2 may be included in the active area AA along a planar area of the window structure WS. For example, a first functional device area E1 may be included at one end portion of the active area AA and may be implemented, e.g., in the form of a camera hole. The second functional device area E2 may serve as a fingerprint sensing area. The functional device may provide a function to the electronic device ED, such as using light and/or sound.

For example, a sensor structure for a touch sensing or a fingerprint sensing may be disposed in the display panel DP, or between the window structure WS and the display panel DP.

The housing HS may serve as a frame structure or a rear housing of the display device DD or the electronic device ED. A cover panel may be disposed between the housing HS and the display panel DP. The housing HS or the cover panel may include a plate (e.g., an SUS plate) which supports the display panel DP, a printed circuit board 400 (see FIG. 15), or the like. The housing HS or the cover panel may include an elastic body for absorbing shock of the display device DD.

Referring to FIG. 15, a plurality of pixels PX11 to PXnm may be arranged in the display area DA of the display device DD or the display panel DP.

In example embodiments, a pixel circuit including scan lines SL1 to SLn (or gate lines) forming first to n^{th} rows, and data lines DL1 to DLm forming first to m^{th} columns, may be arranged on the base substrate 100 of the display device DD or the display panel DP. Each of the pixels PX11 to PXnm may be connected to a corresponding n^{th} row scan line among a plurality of scan lines SL1 to SLn and a corresponding m^{th} column data line among a plurality of data lines DL1 to DLm.

For example, the scan lines SL1 to SLn may be connected to the gate electrode GE included in the transistor. The data lines DL1 to DLm may be connected to, e.g., the contact electrode CNT (e.g., the first contact electrode CNT1) serving as the source electrode.

Each of the pixels PX11 to PXnm may further include the above-described pixel circuit and the light-emitting element LE. Although not illustrated in detail in FIG. 15, the pixel circuit may further include wirings such as a power line, a ground line, etc.

FIG. 15 illustrates that the data lines DL1 to DLm lengthwise extend in the second direction and the scan lines SL1 to SLn lengthwise extend in the first direction, but the construction of the data lines and the gate lines is not limited to that illustrated in FIG. 15.

A peripheral circuit PC may be disposed in the peripheral area PA of the electronic device DD or the non-display area NDA of the display panel DP. For example, the peripheral circuit PC may include a gate driving circuit. The gate driving circuit may be integrated into the display panel DP by an oxide semiconductor gate (OSG) driver circuit process, an amorphous silicon gate (OSG) driver circuit process, or a polysilicon gate (PSG) driver circuit process.

The electronic device ED may further include the printed circuit board 400. Pads 195 of the pixel circuit (e.g., the data lines) may be assembled at one end portion of the non-display area NDA. The printed circuit board 400 may be electrically connected to the pixel circuit through the pads 195. For example, the printed circuit board 400 may be electrically connected to the display panel DP at the pads 195, by a heating-compression process using a conductive intermediate structure such as an anisotropic conductive film (ACF).

The pads 195 and a driving circuit element IC may be electrically connected to each other through the printed circuit board 400. The driving circuit element IC may include an integrated circuit chip. In some embodiments, the integrated circuit chip may be mounted on the printed circuit board 400 in a chip-on-film (COF) form.

The driving circuit element IC may include a driving circuit of the display device DD and a driving circuit (e.g., an application processor chip) of the electronic device ED. The driving circuit element IC may further include a circuit board such as a main board on which a chip including the driving circuit is mounted.

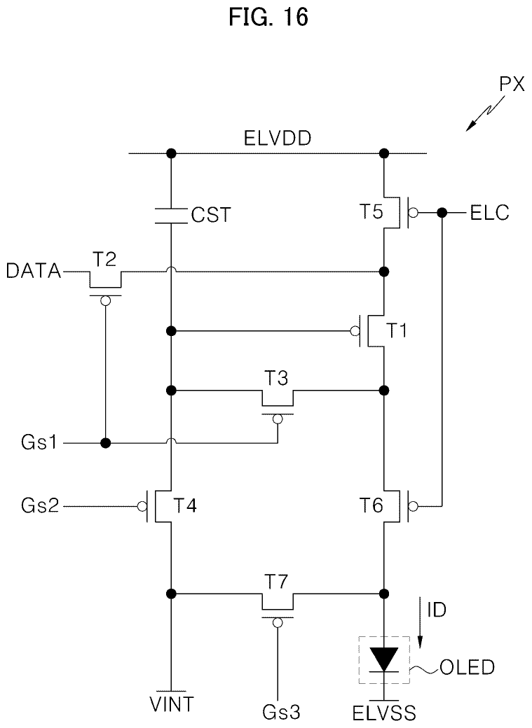

FIG. 16 is a pixel equivalent circuit diagram of a display device DD according to embodiments.

Referring to FIG. 16, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light-emitting diode OLED in response to the emission control signal ELC.

The seventh transistor T7 may include a gate terminal, a first terminal and a second terminal. The gate terminal may receive a third gate signal Gs3. The first terminal may be connected to the organic light-emitting diode OLED. The second terminal may receive the initialization voltage VINT. The seventh transistor T7 may initialize the organic light-emitting diode OLED.

The storage capacitor CST may include a first terminal and a second terminal. The first terminal may receive the high-power supply voltage ELVDD. The second terminal may be connected to the gate terminal of the first transistor T1,

The organic light-emitting diode OLED may include a first terminal and a second terminal. The first terminal may be connected to the sixth transistor T6. The second terminal may receive a low-power supply voltage ELVSS. The organic light-emitting diode OLED may emit a light based on the driving current ID.

In some embodiments, a transistor including the above-described multi-layered contact electrode CNT and the active layer ACT including the silicon semiconductor may be used as the first transistor T1. In some embodiments, a transistor employing a single-layered contact electrode and including an active layer formed of an oxide semiconductor may be used as the second transistor T2.

In FIG. 16, a structure including seven thin film transistors and one storage capacitor CST (e.g., a structure of 7T1C) in each pixel PX is illustrated, but the pixel structure of the display device DD disclosed herein is not limited thereto.

For example, each pixel PX may include two or more transistors, and may have a structure such as 2T1C, 5T1C, 6T1C, 5T2C, 6T2C, or the like.

The display device DD according to embodiments may be applied to various electronic devices. For example, the electronic device ED includes the above-described display device, and may further include a module or a device having other additional functions in addition to the display device DD.

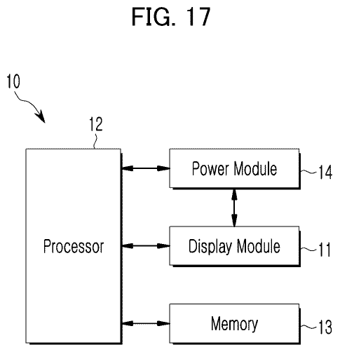

FIG. 17 is a block diagram of an electronic device 10 in accordance with an embodiment.

Referring to FIG. 17, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module which converts a power supplied by the power supply module to a generate power required for the operation of the electronic device 10.

At least one of components of the electronic device 10 as described above may be included in the display device DD according to the above-described embodiments. Additionally, some of individual modules functionally included in one module may be included in the display device DD, and others may be provided separately from the display device DD. For example, the display module 11 may include the display device DD, and the processor 12, the memory 13 and the power module 14 may be provided in the form of another device in the electronic device 10 different from the display device DD.

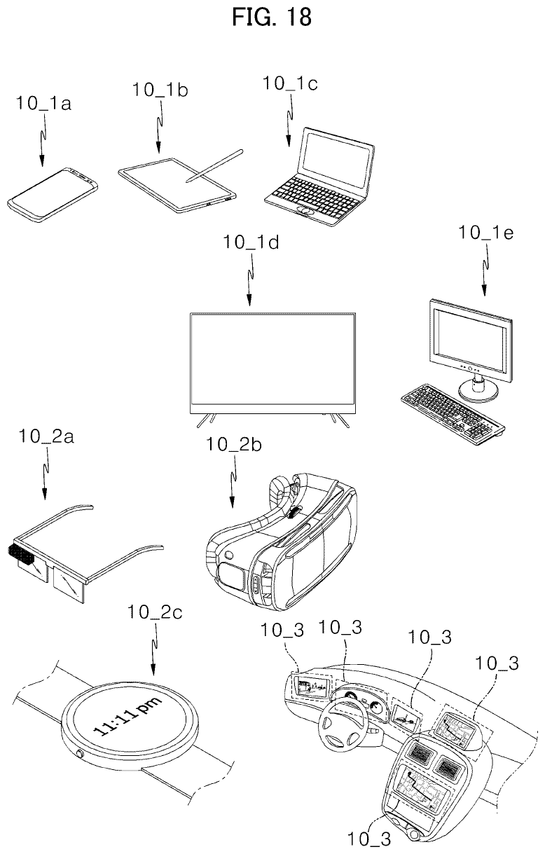

FIG. 18 is a schematic diagram of an electronic device 10 in accordance with various embodiments.

Referring to FIG. 18, non-limiting examples of various electronic devices to which the display device DD according to the above-described embodiments is applied include an electronic device 10 for displaying an image such as a smartphone 10_1a, a tablet PC 10_1b, a laptop 10_1c, a TV 10_1d, a desk monitor 10_1e, and the like, a wearable electronic device including a display module 11 such as smart glasses 10_2a, a head mounted display 10_2b, a smart watch 10_2c, and the like, a vehicle electronic device 10_3 including a display module 11 such as a center information display (CID) disposed at a vehicle instrument panel, a center fascia, a dashboard, etc., a head-up display, a room mirror display, and the like.

In some embodiments, the electronic device 10 may include a virtual reality glass (GVR) or an augmented reality glass.

What is claimed is:

1. A display device, comprising:
a light-emitting element;
a transistor connected to the light-emitting element, the transistor comprising:
an active layer including a contact region and a channel region; and
a gate electrode overlapping the channel region of the active layer;
an insulating layer which is between the active layer and the light-emitting element, the insulating layer including a contact hole therein through which the contact region of the active layer is exposed; and
a contact electrode electrically connecting the light-emitting element to the transistor, at the contact region of the active layer, the contact electrode comprising:
a lower contact comprising:
a first contact portion connected to the contact region of the active layer in the contact hole, and
a first overhang portion which extends from the first contact portion, in a direction away from the contact hole, and has a curved surface; and
an upper contact which is in the contact hole, and directly contacts the lower contact at the curved surface of the first overhang portion.

2. The display device of claim 1, wherein
the first contact portion defines a first recess of the lower contact which is open at a first inlet of the lower contact, the first inlet being defined by the first overhang portion and having a width,
the contact hole has a first width corresponding the first contact portion of the lower contact, and
the width of the first inlet is smaller than the first width of the contact hole.

3. The display device of claim 2, wherein the width of the first inlet is about 50% or less of the first width of the contact hole.

4. The display device of claim 2, wherein the first inlet and the first recess of the lower contact are closed by the upper contact.

5. The display device of claim 4, further comprising an insulating filler in the first recess which is closed by the upper contact.

6. The display device of claim 5, wherein the insulating filler has a void defined therein.

7. The display device of claim 6, wherein the void is surrounded by the insulating filler.

8. The display device of claim 2, wherein
the insulating layer comprises:
a first insulating interlayer covering the active layer and the gate electrode, the first insulating interlayer including a first contact hole defined therein which exposes the contact region of the active layer and has the first width; and
a second insulating interlayer on the first insulating interlayer, the second insulating interlayer including a second contact hole defined therein which exposes the first overhang portion of the lower contact, and
the upper contact comprises:
a second contact portion which contacts the first overhang portion, and covers the first inlet of the lower contact in the second contact hole, and
a second overhang portion which extends from the second contact portion, in a direction away from the second contact hole.

9. The display device of claim 8, wherein a bottom portion of the second contact portion includes a tip portion which protrudes toward a bottom surface of the lower contact.

10. The display device of claim 8, wherein
the second contact portion defines a second recess of the upper contact which is open at a second inlet of the upper contact, the second inlet being defined by the second overhang portion and having a width,
the contact hole has a second width corresponding to the second contact portion of the upper contact,
the width of the second inlet is:
smaller than the second width of the second contact hole, and
greater than or equal to the width of the first inlet of the lower contact.

11. The display device of claim 10, further comprising a planarization layer which is on the second insulating interlayer and extends into the second recess of the upper contact to fill the second recess.

12. The display device of claim 11, wherein the planarization layer which is in the second recess includes a void defined therein.

13. The display device of claim 1, wherein the lower contact includes a first metal layer, a second metal layer and a third metal layer sequentially stacked from an inner wall of the contact hole and from a top surface of the contact region of the active layer.

14. The display device of claim 13, wherein
the first metal layer and the third metal layer include a same metal, and
the second metal layer includes a metal different from that of the first metal layer and the third metal layer, and has a thickness greater than a thickness of each of the first metal layer and the third metal layer.

15. The display device of claim 14, wherein the first metal layer and the third metal layer include titanium, and the second metal layer includes aluminum.

16. A method of providing a display device, the method comprising:
providing a transistor comprising an active layer and a gate electrode which overlaps the active layer, on a base substrate; and
providing a contact electrode which electrically connects the transistor to a light-emitting element, wherein the providing of the contact electrode comprises:
providing a first insulating interlayer covering the gate electrode of the transistor;
etching the first insulating interlayer to provide a first contact hole which is in the first insulating interlayer and exposes the active layer;
providing a lower contact of the contact electrode, the lower contact comprising:
a first contact portion which is in the first contact hole, defines a first recess of the lower contact, and is connected to the active layer, and
a first overhang portion which extends from the first contact portion and to an outside of the first contact hole;
providing a second insulating interlayer on the first insulating interlayer, extending into the first recess of the lower contact, and covering the lower contact;
etching the second insulating interlayer to provide a second contact hole which is in the second insulating interlayer, and exposes the first overhang portion of the lower contact, the etching of the second insulating interlayer separating a portion of the second insulating interlayer which is in the first recess from a remainder of the second insulating interlayer; and
providing an upper contact of the contact electrode which is in the second contact hole and contacts the lower contact at the first overhang portion of the lower contact.

17. The method of claim 16, wherein the providing of the second insulating interlayer forms a void in the portion of the second insulating interlayer which is in the first recess.

18. The method of claim 17, wherein the portion of the second insulating interlayer fills the first recess.

19. An electronic device, comprising:
a display device;
a memory; and
a processor executing data included in the memory and controlling an operation of the display device,
wherein the display device comprises:
a light-emitting element;
a transistor connected to the light-emitting element, the transistor comprising:
an active layer including a contact region and a channel region; and
a gate electrode overlapping the channel region of the active layer;
an insulating layer which is between the active layer and the light-emitting element, the insulating interlayer including a contact hole therein through which the contact region of the active layer is exposed; and
a contact electrode connecting the light-emitting element to the transistor, at the contact region of the active layer, the contact electrode comprising:
a lower contact comprising
a first contact portion which connected to the contact region of the active layer in the contact hole, and
a first overhang portion which extends from the first contact portion, in a direction away from the contact hole, and has a curved surface; and
an upper contact which is in the contact hole, and directly contacts the lower contact at the curved surface of the first overhang portion.

20. The electronic device of claim 19, wherein the electronic device comprises a virtual reality glass, an augmented reality glass, a smart phone, a tablet PC, a laptop, a television, a desk monitor, smart glasses, a head-mounted display, a smart watch or a vehicle display.
